(19) United States
(12) Patent Application Publication
(10) Pub. No.: US 2017/0242503 A1
(43) Pub. Date: Aug. 24, 2017

(54) SMUDGE, SCRATCH AND WEAR RESISTANT GLASS VIA ION IMPLANTATION

(71) Applicant: Intevac, Inc., Santa Clara, CA (US)

(72) Inventors: Babak Adibi, Los Altos, CA (US); Terry Bluck, Santa Clara, CA (US)

(21) Appl. No.: 15/437,304

(22) Filed: Feb. 20, 2017

Related U.S. Application Data
(60) Provisional application No. 62/297,695, filed on Feb. 19, 2016.

(51) Int. Cl. G06F 3/041; H01L 21/265

(52) U.S. Cl. CPC G06F 3/041; H01L 21/265; G06F 2203/04103

(57) ABSTRACT

Mechanical properties of a cover glass for a touch screen are improved by ion implanting the front surface. The implant process uses non-mass analyzed ions that physically embed in voids between inter-connected molecules of the glass. The embedded ions create compression stress on the molecular structure, thus enhancing the mechanical properties of the glass to avoid scratches. Also, implanting ions containing fluoride enhances the hydrophobic and oleophobis properties of the glass to prevent finger prints.

### RELATED APPLICATION

This application claims priority benefit from U.S. Provisional Application Ser. No. 62/297,695, filed on Feb. 19, 2016, the disclosure of which is incorporated herein by reference in its entirety.

### BACKGROUND

1. Field

This disclosure relates to enhancing the properties of glass used for digital devices, such as cover glass for touch screen displays.

2. Related Art and Problem Being Solved

The top surface of a cover glass, such as used on displays for applications such as cell phones, tablets and automotive dashes, needs to be scratch, wear and finger print resistant. To achieve scratch and wear resistant a protective coating can be applied on to the top surface of the glass. A typical choice of coating would be diamond like carbon (DLC). However, these coatings can adversely affect the color and light transmission of the glass. To avoid or reduce these optical affects the film may be applied very thin or with lower density, but this can adversely changes the wear and scratch resistance property of the film.

Smudge or anti-finger print behavior is important and many protective coatings are not hydrophobic enough in nature. A water contact angle greater than 100 degrees is desired. These hydrophobic materials do not adhere to a DLC surface due to the lack of dangling bonds.

Anti-reflective coatings are also very desirable for these types of devices; however, AR coatings are typically not durable and can easily be damaged. Any damage to an AR coating is very noticeable by the human eye and can in some cases ruin the device.

In addition there can be adhesion and wear-off issues with the hydrophobic anti-finger print coatings, such as fluoroalkylsilane (FAS).

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to aspects of the invention, a DLC coating is eliminated and replaced by treatment of the glass. In embodiments of the invention implanted species selected from CyHx, CyFx, ByFx, AlCl₃, NxFy, SiH₄, N2, and organometallic precursors such as TMA (Tetramethylaluminum), that densify the top surface of the glass and introduce compressive strain in the molecular structure of the glass or AR coating, thereby enhancing its mechanical properties. In embodiments of the invention, implanted CyFx or ByFx compounds create a hydrophobic surface and eliminate the need for additional coatings and equipment.

According to disclosed aspects, a cover glass used for touch screen devices is provided, comprising: a glass plate having front surface configured to receive contact of a user's finger, the glass plate having glass molecules interconnected by inter-molecules bonds and further having implanted ions positioned among the inter-connected molecules but having no bonds to the interconnected molecules. The cover glass may further comprise an implanted hydrophobic layer on the front surface. The implanted ions are selected from one or more of: CxHy, CxFy, BxFy, NxFy, TMA, SiH4 and N2. The hydrophobic layer comprises implanted CxFy, NxFy or BxFy. The implanted ions can extend to a depth of less than 100 angstrom below the front surface. The implanted ions may comprise deeply implanted ions selected from CxHy or N2, and surface implanted ions selected from CxFy, BxFy and NxFy, wherein the deeply implanted ions extend to a depth of less than 100 angstrom below the front surface, and the surface implanted ions extend to a depth of less than 5 angstrom below the front surface. The cover glass may further comprise: a silicon layer formed over the front surface; a silicon dioxide layer formed over the silicon layer; and an anti-finger printing layer formed over the silicon dioxide layer. The silicon layer may have thickness of 5-10 angstrom and the silicon dioxide layer may have a thickness of 10-30 angstrom.

According to other disclosed aspects, a cover glass used for touch screen devices is provided, comprising: a glass plate having front surface configured to receive contact of a user's finger; an anti-reflective (AR) structure formed over the front surface, the anti-reflective structure comprising interleaved layers of different index of refraction and culminating with a top AR layer; wherein the top AR layer comprises interconnected molecules interconnected by inter-molecules bonds and further having implanted ions positioned among the inter-connected molecules but having no bonds to the interconnected molecules. The the implanted ion are selected from one or more of: CxHy, CxFy, BxFy, NxFy, TMA, SiH4 and N2. The cover glass may further comprise: a silicon layer formed over the top AR layer; a silicon dioxide layer formed over the silicon layer; and an anti-finger printing layer formed over the silicon dioxide layer. The silicon layer may have thickness of 5-10 angstrom and the silicon dioxide layer may have a thickness of 10-30 angstrom. The implanted ions may extend to a depth of 10-50 angstroms inside the top AR layer.

According to further aspects a method for enhancing properties of glass substrate is provided, comprising: cleaning a front surface of the glass; implanting the glass substrate through the front surface of the glass to a depth of up to 100 angstrom. Cleaning the front surface may comprise exposing the front surface to plasma. Implanting the glass substrate may comprise generating plasma using precursor gas containing one or more of: CxHy, CxFy, BxFy, NxFy, TMA, SiH4 and N2. Implanting the glass substrate may comprise implanting ions at the energy between 100-5000 eV. Implanting the glass substrate may comprise implanting ions at the ion current between 100-500 mA. The method may further comprise: forming a silicon layer over the front surface of the glass; forming a silicon dioxide layer over the silicon layer; and forming an anti-finger printing layer over the silicon dioxide layer. Forming a silicon layer may be performed to a thickness of 5-10 angstrom and forming a silicon dioxide layer may be performed to a thickness of 10-30 angstrom.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

One or more embodiments of the present invention are illustrated by way of example and not limitation in the figures of the accompanying drawings, in which like references indicate similar elements and in which:

FIG. 1 is a schematic illustration of molecular structure of glass.

FIG. 2 is a schematic of molecular structure near the surface of glass, according to an embodiment of the invention.

FIG. 3 illustrates an embodiment of an ion implant chamber for implanting a glass substrate.

FIG. 4 illustrates an embodiment of a system for ion implanting of cover glass.

FIG. 5 illustrates an embodiment for producing cover glass having improved mechanical properties.

FIG. 6 illustrates an embodiment for producing cover glass having anti-reflective coating with improved mechanical properties.

FIG. 7 illustrates an embodiment for producing cover glass having anti-reflective coating with improved mechanical and anti-finger printing properties.

FIG. 8 illustrates an embodiment for producing cover glass having improved mechanical and anti-finger printing properties.

FIG. 9 illustrates an embodiment for producing cover glass having improved mechanical and anti-finger printing properties with DLC top layer.

FIG. 10 illustrates an embodiment for producing cover glass having improved mechanical and anti-finger printing properties with DLC top layer and enhanced nitride/oxide underlayer.

### DETAILED DESCRIPTION

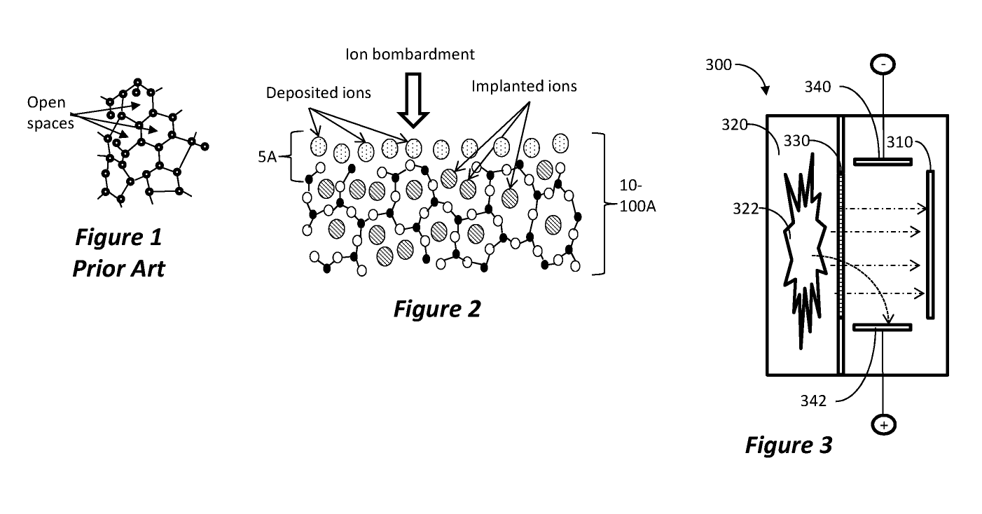

Glass is an amorphous solid of bonded molecules. FIG. 1 is a schematic illustration of molecular structure of glass. Circles designate glass molecules, while lines designate inter-molecular bonding. The surface of a glass is often smooth since during glass formation the molecules of the supercooled liquid are not forced to dispose in rigid crystal geometries and can follow surface tension, which imposes a microscopically smooth surface. However, the reduction of surface tension weakens the scratch resistance property of the glass. As shown in FIG. 1, the molecular structure of glass has many “voids” or open spaces. According to embodiments of the invention, ion implant is used to physically “fill” these holes with other elements, without making inter-molecular bonds. The ion implantation hardens and densifies the film by introducing stresses into the existing molecular structure, especially near the surface.

FIG. 2 is a schematic of molecular structure near the surface of glass, according to an embodiment of the invention. Blank and filled circles designate glass molecule while lines designate inter-molecular bonding of the glass molecules. As illustrated in FIG. 2, energetic ions bombard the surface of the glass such that ions embed (patterned circles) into voids of the existing film, increasing the density and introducing compressive stress, thus enhancing the mechanical properties of the film. The ions are introduced in a physical process, such that generally the ions do not form new bonds with the glass molecules. It is possible, though, that due to heat generated during the implantation process some self-annealing will occur and some implanted ions will develop new bonds, yet many implanted ions will not form new bonds and will just exert stress on existing glass bonds. Notably, the implantation is performed only to modify the mechanical properties of the glass, as opposed to cases where the ion implantation is done to dope the material, thus changing its electrical properties. Therefore, in this embodiment the process is designed to cause embedded ions to simply occupy available spaces within the molecular structure of the glass, without forming bonds with the molecules of the glass.

In certain embodiments the surface properties of the glass can also be modified to create a hydrophobic surface. This is illustrated by the implanted molecules shown in dotted circles. In this case, the ions are implanted close to the surface of the glass, or are deposited using ion implantation process, to generate a hydrophobic surface. The ions are implanted at a very low energy, so that they are present mostly, if not exclusively, on or near the surface of the disk, e.g., to a depth up to 5 angstrom. The “stress inducing” ions are implanted to a depth beyond the first 5 angstrom, e.g., to a depth of 10-100 angstrom.

The glass is implanted by an ion beam operating at an energy level so as to densify the top layer of the glass. This energy will be species dependent (i.e., based upon the size of the implanted ions). Smaller ions will require less energy than larger ions. Consequently, for a given implanter energy, smaller ions will embed deeper into the glass than larger ions. In one embodiment, the ion beam has a diameter at least as large as to simultaneously cover the entire surface of the glass plate. In one embodiment the implanter employs remote plasma having a gridded opening, such that plasma cannot reach the surface of the glass, but ions from the plasma can pass through the grid and reach and be implanted in the glass.

Also, in disclosed embodiments using the gridded plasma chamber the implanted ions are not mass analyzed, such that all of the molecule species present in the plasma can be implanted. An advantage of non-mass analyzed ion implantation is that the ion implantation depth profile is rather broad as compared to mass analyzed implant. As a result, the atomic concentration profile is very high at very near surface and then tails off with depth, such that the top surface of the substrate becomes the strongest mechanically, while the remaining bulk of the substrate is not affected by the implant.

The implantation gas could be from any one of the following: CxHy, CxFy, BxFy, NxFy and N2. For deeper penetration, it is beneficial to use CxHy or N2, as these are smaller molecules that will implant deeper into the DLC layer. However, for improved hydrophobic property of the surface, it is beneficial to use one of CxFy, BxFy, NxFy, as the fluorine will enhance the hydrophobic property, and the molecule is relatively large, such that it will not penetrate deeply and will remain close to the surface. In some embodiments a first implant process uses the smaller molecules, e.g., CxHy or N2, for deeper implant and enhanced mechanical properties of the glass, followed by implant of one of CxFy, BxFy, NxFy, for improving the hydrophobic properties of the surface of the glass. Also, the implanting energy may be controlled so as to first cause physical implant of ions, and thereafter reducing the energy to perform deposition of fluorinated ions on the surface—still using ion implant processing—and thereby form a hydrophobic layer on the surface. In yet other embodiments aluminum species are implanted so as to convert the top surface of the glass to sapphire-like top layer, thus enhancing the surface's mechanical properties. For example, aluminum chloride (AlCl₃) source can be used to generate Al²⁺ ions for implanting into the top surface of the glass plate.

FIG. 3 illustrates an embodiment wherein the cover glass plate 310 is implanted only on one side, although the features illustrated in FIG. 3 may be implemented in a chamber wherein the glass plate 310 is implanted simultaneously from both sides. Also, in this embodiment the glass substrates are transported in a vertical orientation on the carriers so as to reduce particle defects, although a system may also be devised wherein the glass substrates are transported in a horizontal orientation. Chamber 300 has a plasma cage 320 wherein plasma 322 is maintained. As ion species are generated within plasma 322, the ions pass through grid 330 towards glass plate 310, as illustrated by the dash-dot arrows. The size of the grid 330 is at least as large as the size of the glass plate 310.

During processing large particles may form and may land on the glass plate 310, causing defects. In order to avoid such an occurrence, in this embodiment opposing electrodes 340 and 342 are placed in the path between the grid and the disk. One electrode (here 342) is biased to positive potential while the other (here 340) biased to negative potential. Consequently, when a particle enters the area between the grid 330 and disk 310, it would be attracted to one of the electrodes 340 or 342, depending on the charge on the particle, as illustrated by the curved dashed arrow.

Specifically, as illustrated in FIG. 3, the glass 310 is transported within the processing section of chamber 300, e.g., by a carrier travelling on tracks or rails (not shown for clarity) and is positioned at a substrate processing station. The ion travel section is defined as the space between the grid 330 and the substrate processing station. The electrode assembly, in FIG. 3 comprising two electrodes 340 and 342, is situated between the grid 330 and the substrate processing station, but outside of the ion travel section, i.e., beyond the area occupied by ions traveling from the grid 330 towards the glass plate 310. One electrode is biased positively, while the other is biased negatively. Thus, any particles traveling within the ion travel section are attracted to the electrodes and will not land on the disk 310.

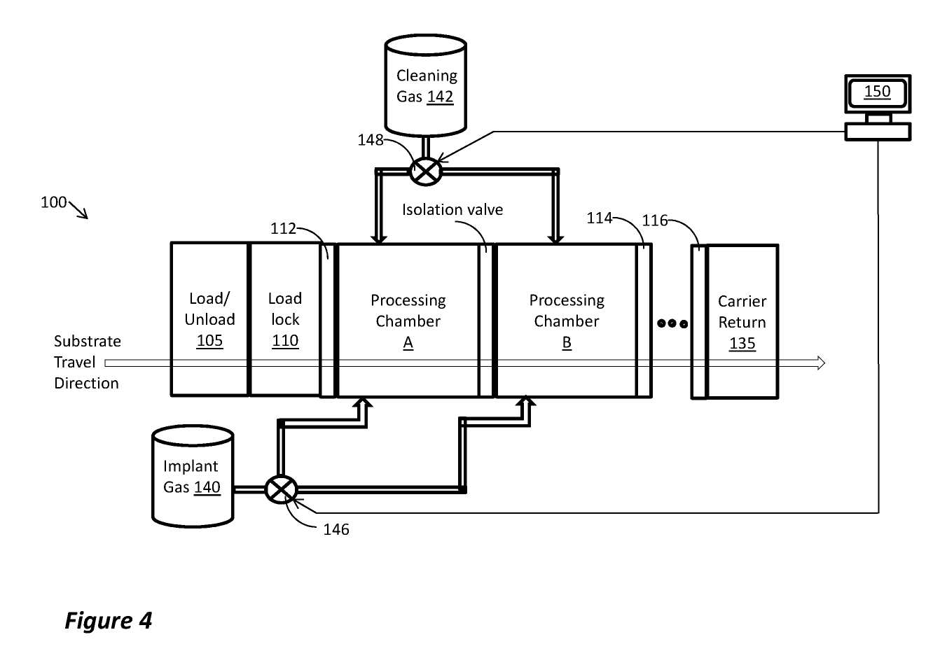

FIG. 4 illustrates an embodiment of a system for ion implanting of cover glass. In this embodiment there are two process stations for ion implantation with high vacuum isolation valves in between. The process occurs in one station while cleaning plasma is run in the other so as to clean the interior of the chamber. The chambers then alternate every other substrate. This keeps the throughput high and keeps the chambers clean, to ensure low particles generation during the implantation process.

This embodiment is especially beneficial for ion implant using a hydrocarbon gas, since there would be deposition on the walls and grids. In order to prevent this from creating particles, the carbon build up must be stripped by running oxygen plasma inside the chamber. The glass plate cannot be in the chamber during the oxygen plasma. So there are two identical chambers which alternate between implantation and clean. The simultaneous operation in the two chambers is considered as one cycle. Process gas supply 140 is coupled to both chambers via a toggle valve 146. Cleaning gas supply 142 is coupled to both chambers via toggle valve 148. In operation, the two toggle switches 146 and 148 are counter-synchronized. That is, when one valve is open for one chamber, the other valve if closed for that chamber. For example, when toggle valve 146 is open for chamber A and closed for chamber B, toggle valve 148 is closed for chamber A and open for chamber B.

The glass plate is only in the chamber that performs implantation process. Say there are two chambers (A & B) adjacent to each other with A being the first chamber reached as the glass plate travels thru the system. Then, on the even cycle the glass plate moves into chamber A and is implanted while chamber B is stripped. On the next machine cycle the processed glass plate exits chamber A and passes through to exit chamber B as well. A fresh glass plate to be processed moves through chamber A and stops in chamber B for processing. Chamber A remains empty. Chamber B performs the implant process while chamber A is stripped. The cycle repeats continuously.

A controller 150 controls the operation of the system. It directs the transportation of the glass plates and commands the ignition and maintenance of plasma within the chambers. The controller 150 also controls the valves 146 and 148.

Below are process flows for various embodiments providing processes for enhancing properties of glass plate. The disclosed processes may be performed in equipment designed to perform these process steps, such as those shown in FIGS. 3 and 4, although other ion implant systems may be used to carry out the described processes. For example, a system may be used wherein the substrate travels continuously across the ion beam, rather than being stationary during the implant process.

The implantation in these embodiments is done with a non-mass analyzed gridded ion beam source, such that all of the ion species within the plasma are implanted into the glass. For example, the molecule CH4 would be broken-up in the plasma to various ions, e.g., C, H and CH4, such that the heavy molecule CH4 would be implanted near the surface, while the lighter molecules C⁺ and H⁺ would be implanted deeper into the glass plate, with H reaching the deepest implantation. The ion energy is set to between 100-5000 eV, while the ion current is set to between 100-500 mA.

The disclosed oxides and argon layer depositions would be done with any combination of the following deposition sources: rotatable magnetrons (cylindrical targets), linear magnetrons or linear PECVD plasma sources. All sources should be run in dual cathode AC mode to avoid the vanishing anode effect.

Precursors for the ion implantation could be from any of the following gases: CyHx, CyFx, ByFx, TMA (Tetramethylammonium), AlCl₃, NxFy, SiH₄ and N2, or any other precursor which would densify the top surface without affecting the glass such as to make it unacceptable for display use.

### Process Flow for Durable Cover Glass:

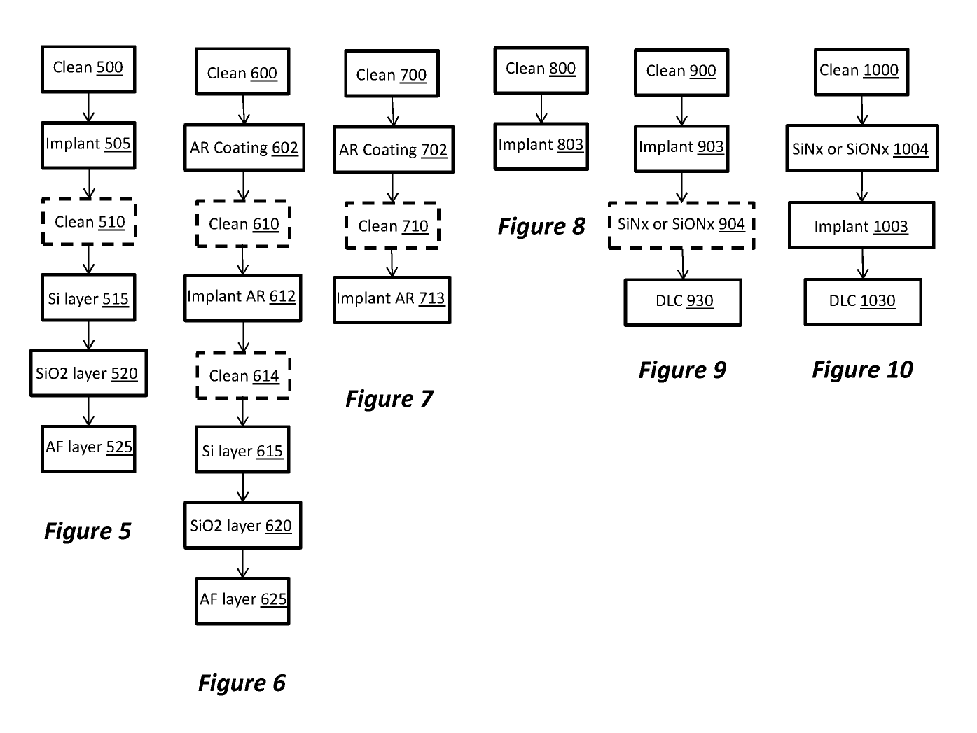

FIG. 5 illustrates an embodiment for producing cover glass having improved mechanical properties. In step 500 the glass plate is cleaned, e.g., by plasma etch. Then, in step 505, the top surface of the glass plate is implanted with the desired species. For wear and scratch improvements it is desirable to use large ions so as to impart large compressive stresses in the molecular structure of the glass. Optionally, in step 510 the glass is cleaned again using plasma etch. This clean step may not be required when the next deposition step is done in-situ or within the same system without breaking vacuum. In the next step 515, a silicon layer is formed, mostly to act as foundation for the deposition of the SiO layer in step 520. The silicon layer may be formed to a thickness of 5-10 angstrom and the silicon dioxide layer may be formed to a thickness of 10-30 angstrom. In step 525 an anti-fingerprint layer is deposited. The anti-fingerprint coatings (also referred to as oleophobic coatings—AFC) are known to provide oil-repelling properties to glass substrates, such that fingerprints do not adhere well and are easily wiped off. To produce a long lasting oleophobic coating that doesn't wear off easily, the coating process is performed by deposition of the SiO2 adhesion layer prior to the deposition of the AFC. The AFC layer may be, e.g., FAS (fluoroalkylsilane).

### Process Flow for Durable AR on Cover Glass:

FIG. 6 illustrates an embodiment for producing cover glass having anti-reflective coating with improved mechanical properties. In step 600 the glass plate is cleaned, e.g., by plasma etch. Then, in step 602, an anti-reflective (AR) coating is formed on the top surface of the glass plate. The AR coating is generally formed by depositing several interleaved layers of different index of refraction, culminating with a top AR layer. Optionally, in step 610 the glass is cleaned again using plasma etch. Then, in step 612 the top layer of the AR coating is implanted with the desired species. The ions may be implanted to a depth of 10-50 angstroms inside the top AR layer. Optionally, in step 614 the glass is cleaned again using plasma etch. In the next step 615, a silicon layer is formed and in step 620 the SiO layer is formed. The silicon layer may be formed to a thickness of 5-10 angstrom and the silicon dioxide layer may be formed to a thickness of 10-30 angstrom. In step 625 an anti-fingerprint layer is deposited.

Process Flow for Durable AR with Hydrophobic Surface:

FIG. 7 illustrates an embodiment for producing cover glass having anti-reflective coating with improved mechanical and anti-finger printing properties. In step 700 the glass plate is cleaned, e.g., by plasma etch. Then, in step 702, an anti-reflective (AR) coating is formed on the top surface of the glass plate. The AR coating is generally formed by depositing several interleaved layers of different index of refraction. Optionally, in step 710 the glass is cleaned again using plasma etch. Then, in step 713 the top layer of the AR coating is implanted with species that enhance the anti-fingerprint resistance of the top AR coating layer. The species may be selected from, e.g., CxFy, BxFy, NxFy, or other species that would contribute fluorine to the top AR layer.

Process Flow for Durable glass with Hydrophobic Surface:

FIG. 8 illustrates an embodiment for producing cover glass having improved mechanical and anti-finger printing properties. In step 800 the glass plate is cleaned, e.g., by plasma etch. In step 803 the top layer of the glass plate is implanted with species that enhance the anti-fingerprint resistance of the glass plate. The species may be selected from, e.g., CxFy, BxFy, NxFy, or other species that would contribute fluorine to the top AR layer.

Process Flow for Durable glass with DLC Top Coat:

FIG. 9 illustrates an embodiment for producing cover glass having improved mechanical and anti-finger printing properties with DLC top layer. According to this process, the glass is cleaned in step 900. Then the glass is implanted on its front surface. In optional step 904 an underlayer is formed using, e.g., chemical or vapor deposition process. The underlayer may include SiNx, SiONx or a combination of both. Thereafter, a diamond-like coating (DLC) later is formed, using, e.g., physical vapor deposition. Thus, in this method the mechanical properties of the surface of the glass are enhanced by the physical implantation of ions that create stress in the molecular structure of the glass below the surface. The mechanical properties are further enhanced by depositing a DLC layer over the front surface of the glass. The optional underlayer serves to improve the adhesion of the DLC layer to the glass.

FIG. 10 illustrates an embodiment for producing cover glass having improved mechanical and anti-finger printing properties with DLC top layer and enhanced nitride/oxide underlayer. According to this process, the glass is cleaned in step 1000. Then in step 1004 an underlayer is formed using, e.g., chemical or vapor deposition process. The underlayer may include SiNx, SiONx or a combination of both. Then the front surface of the glass is implanted through the underlayer. Consequently, ions are embedded in both the underlayer and the glass, enhancing the mechanical properties of both the underlayer and the glass. Thereafter, a diamond-like coating (DLC) later is formed, using, e.g., physical vapor deposition. Thus, in this method the mechanical properties of the surface of the glass and the underlayer are enhanced by the physical implantation of ions that create stress in the molecular structure of the glass and the underlayer. The mechanical properties are further enhanced by depositing a DLC layer over the front surface of the glass. The underlayer serves to improve the adhesion of the DLC layer to the glass, but its mechanical properties are enhanced by the ion implant.

While this invention has been discussed in terms of exemplary embodiments of specific materials, and specific steps, it should be understood by those skilled in the art that variations of these specific examples may be made and/or used and that such structures and methods will follow from the understanding imparted by the practices described and illustrated as well as the discussions of operations as to facilitate modifications that may be made without departing from the scope of the invention defined by the appended claims.

1. A cover glass used for touch screen devices, comprising:
a glass plate having front surface configured to receive contact of a user's finger, the glass plate having glass molecules interconnected by inter-molecules bonds and further having implanted ions positioned among the inter-connected molecules but having no bonds to the interconnected molecules.

2. The cover glass of claim 1, further comprising an implanted hydrophobic layer on the front surface.

3. The cover glass of claim 1, wherein the implanted ion are selected from one or more of:
CxHy, CxFy, BxFy, NxFy, TMA, SiH₄ and N2.

4. The cover glass of claim 2, wherein the hydrophobic layer comprises implanted CxFy, NxFy or BxFy.

5. The cover glass of claim 3, wherein the implanted ions extend to a depth of less than 100 angstrom below the front surface.

6. The cover glass of claim 1, wherein the implanted ions comprise deeply implanted ions selected from CxHy or N2, and surface implanted ions selected from CxFy, BxFy and NxFy, wherein the deeply implanted ions extend to a depth of less than 100 angstrom below the front surface, and the surface implanted ions extend to a depth of less than 5 angstrom below the front surface.

7. The cover glass of claim 1, further comprising:
a silicon layer formed over the front surface;
a silicon dioxide layer formed over the silicon layer; and
an anti-finger printing layer formed over the silicon dioxide layer.

8. The cover glass of claim 1, further comprising:
an underlayer formed on the front surface; and,
a diamond like coating (DLC) layer formed over the underlayer.

9. The cover glass of claim 1, wherein the underlayer comprises one of SiNx or SiONx.

10. The cover glass of claim 8, wherein the underlayer comprises underlayer molecules interconnected by inter-molecules bonds and further having implanted ions positioned among the inter-connected molecules but having no bonds to the interconnected molecules.

11. The cover glass of claim 1, wherein the silicon layer has thickness of 5-10 angstrom and the silicon dioxide layer has a thickness of 10-30 angstrom.

12. A cover glass used for touch screen devices, comprising:
a glass plate having front surface configured to receive contact of a user's finger;
an anti-reflective (AR) structure formed over the front surface, the anti-reflective structure comprising interleaved layers of different index of refraction and culminating with a top AR layer;
wherein the top AR layer comprises interconnected molecules interconnected by inter-molecules bonds and further having implanted ions positioned among the inter-connected molecules but having no bonds to the interconnected molecules.

13. The cover glass of claim 12, wherein the implanted ion are selected from one or more of:
CxHy, CxFy, BxFy, NxFy, TMA, SiH₄ and N2.

14. The cover glass of claim 13, further comprising:
a silicon layer formed over the top AR layer;
a silicon dioxide layer formed over the silicon layer; and
an anti-finger printing layer formed over the silicon dioxide layer.

15. The cover glass of claim 14, wherein the silicon layer has thickness of 5-10 angstrom and the silicon dioxide layer has a thickness of 10-30 angstrom.

16. The cover glass of claim 12, wherein the implanted ions extend to a depth of 10-50 angstroms inside the top AR layer.

17. A method for enhancing properties of glass substrate, comprising:
cleaning a front surface of the glass;
implanting the glass substrate through the front surface of the glass to a depth of up to 100 angstrom.

18. The method of claim 17, wherein cleaning the front surface comprises exposing the front surface to plasma.

19. The method of claim 17, wherein implanting the glass substrate comprises generating plasma using precursor gas containing one or more of: CxHy, CxFy, BxFy, NxFy, TMA, SiH₄ and N2.

20. The method of claim 17, wherein implanting the glass substrate comprises implanting ions at the energy between 100-5000 eV.

21. The method of claim 17, wherein implanting the glass substrate comprises implanting ions at the ion current between 100-500 mA.

22. The method of claim 17, further comprising:
forming a silicon layer over the front surface of the glass;
forming a silicon dioxide layer over the silicon layer; and
forming an anti-finger printing layer over the silicon dioxide layer.

23. The method of claim 22, wherein forming a silicon layer is performed to a thickness of 5-10 angstrom and forming a silicon dioxide layer is performed to a thickness of 10-30 angstrom.

24. The method of claim 17, further comprising:
forming an underlayer over the front surface of the glass;
forming a diamond-like coating (DLC) layer over the underlayer.

25. The method of claim 24, wherein implanting the glass substrate comprises implanting the glass through the underlayer.
